(19) United States
(12) Patent Application Publication
(10) Pub. No.: US 2025/0233433 A1
(43) Pub. Date: Jul. 17, 2025

(54) MODULAR STORAGE AND CHARGING SYSTEM

(71) Applicant: TRIPLE CLOUD, Little Canada, MN (US)

(72) Inventor: Carly Zucker, Scottsdale, AZ (US)

(21) Appl. No.: 19/018,828

(22) Filed: Jan. 13, 2025

Related U.S. Application Data
(60) Provisional application No. 63/620,590, filed on Jan. 12, 2024.

(51) Int. Cl. H02J 7/00; H05K 5/02

(52) U.S. Cl. CPC H02J 7/0044; H02J 7/0047; H05K 5/0234; H05K 5/0286

(57) ABSTRACT

A modular charging system can include a charging base and a plurality of storage and charging containers. The charging base can include a power adapter configured to provide power to the modular charging system and a plurality of base-to-container receptacles. Each first base-to-container receptacle can include a first electrical connector connected to the power adapter. A charging interface can be disposed of within each storage and charging container and connected to the power adapter to convey a charge from the power adapter to a mobile electronic device stored within each storage and charging container. A container-to-container receptacle can include a second electrical connection connected to the first electrical connection. Each storage and charging container can be configured to be removably coupled to the charging base via any one of the plurality of base-to-container receptacles and another storage and charging container via the container-to-container receptacle.

### CLAIM OF PRIORITY

This patent application claims the benefit of priority, under 35 U.S.C. Section 119(e), to Carly Zucker U.S. Patent Application Ser. No. 63/620,590, entitled MODULAR STORAGE AND CHARGING SYSTEM FOR PERSONAL ELECTRONIC DEVICES,” filed on Jan. 12, 2024 (Attorney Docket No. 6412.001PRV), which is hereby incorporated by reference herein in its entirety.

### TECHNICAL FIELD

Examples described herein generally relate to charging and storage devices. More specifically, the examples described herein relate to modular storage and charging systems for personal electronic devices.

### BACKGROUND

The proliferation of mobile electronic devices such as smartphones, tablets, laptops, and wearable technology has significantly increased over the last few years. With this increase has come the need for efficient and secure charging and storage solutions, especially in environments where multiple devices are used by individuals, such as in offices, educational institutions, public charging stations, or the like. These solutions are also sought out for in environments where people tend to spend long days not near electrical outlets, such as competitions, conventions, sporting events, or the like.

### BRIEF DESCRIPTION OF THE DRAWINGS

Various examples are illustrated in the figures of the accompanying drawings. Such examples are demonstrative and not intended to be exhaustive or exclusive examples of the present subject matter.

FIG. 1 illustrates a schematic diagram of an example of a modular storage and charging system.

FIG. 2 illustrates a block diagram of an example system for modular storage and charging of mobile electronic devices.

FIG. 3 illustrates a schematic diagram of an example of a charging base.

FIG. 4A illustrates a schematic diagram of a bottom view of a storage and charging container.

FIG. 4B illustrates a schematic diagram of a top view of a storage and charging container.

FIGS. 5-6 illustrate a schematic diagram of an example of a modular storage and charging system.

FIG. 7 is a block diagram illustrating an example of a machine upon which one or more examples may be implemented.

### DETAILED DESCRIPTION

Traditional charging solutions often involve individual chargers for each device, leading to clutter and inefficient use of space. Moreover, security concerns arise when devices are left unattended while charging in public or semi-public areas. There is a growing demand for systems that can accommodate multiple devices, offer secure storage during charging, and provide flexibility in terms of the number and type of devices that can be charged simultaneously.

The current market includes various charging stations and storage units, but many lack modularity and the ability to adapt to different device sizes and charging requirements. Additionally, existing systems may not provide adequate security features to prevent unauthorized access to the devices while they are being stored and charged. The present disclosure seeks to address these and other issues by providing a modular storage and charging system that is adaptable, secure, and capable of accommodating a variety of personal electronic devices.

In examples, a modular system for storing and charging mobile electronic devices, the modular system including: a charging base including: a power adapter to provide power to the modular system; and a first base-to-container receptacle including: a first electrical connection connected to the power adapter; a first storage and charging container configured to be removably coupled to the first base-to-container receptacle, the first storage and charging container including: a first charging interface disposed within the first storage and charging container, the first charging interface connected to the power adapter via the first electrical connection, the first charging interface configured to convey a first charge from the power adapter to a first mobile electronic device; and a first container-to-container receptacle including: a second electrical connection connected to either the first electrical connection or the power adapter; and a second storage and charging container configured to be removably coupled to the first container-to-container receptacle, the second storage and charging container including: a second charging interface disposed within the second storage and charging container, the second charging interface connected to the power adapter via the second electrical connection, the second charging interface configured to convey a second charge from the power adapter to a second mobile electronic device.

In examples, a modular charging system including: a charging base including: a power adapter to provide power to the modular charging system; and a plurality of base-to-container receptacles, each base-to-container receptacles including: a first electrical connection connected to the power adapter; and a plurality of storage and charging containers, each storage and charging container including: a charging interface disposed within each storage and charging container, the charging interface connected to the power adapter and configured to convey a charge from the power adapter to a mobile electronic device stored within each storage and charging container; and a container-to-container receptacle including: a second electrical connection connected to either the first electrical connection or the power adapter; wherein each storage and charging container configured to be removably coupled to the charging base via any one of the plurality of base-to-container receptacles, and configured to be removably coupled to another storage and charging container via the container-to-container receptacle.

The above discussion is intended to provide an overview of subject matter of the present patent application. It is not intended to provide an exclusive or exhaustive explanation of the invention. The description below is included to provide further information about the present systems and techniques.

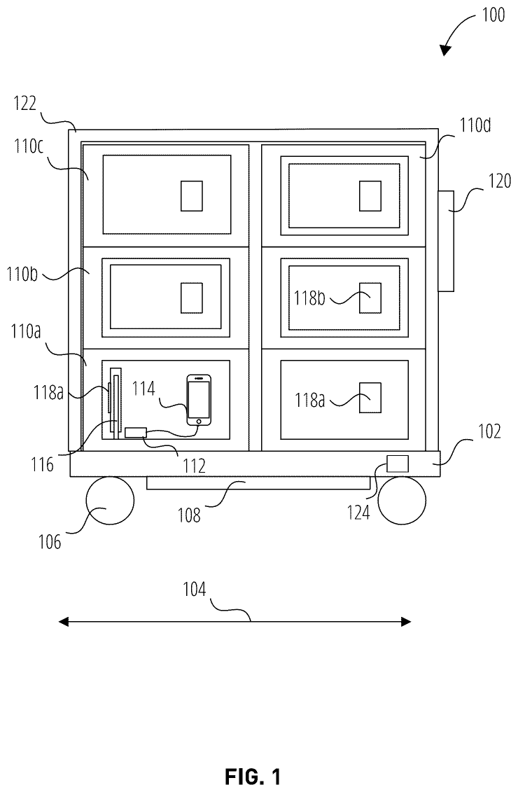

FIG. 1 illustrates a schematic diagram of an example of a modular storage and charging system 100. The modular storage and charging system 100 can be configured to be moveable and modular, such that the number of separate storage and charging containers can be adjusted to meet demand, and the system can be flexible and used for many different purposes. The modular storage and charging system 100 can include a charging base 102, a power adapter 108, a storage and charging container 110 (e.g., a storage and charging container 110a, a storage and charging container 110b, a storage and charging container 110c, a storage and charging container 110d, . . . and a storage and charging container 110n), a locking mechanism 116, a user interface 118 (e.g., a user interface 118a, a user interface 118b, . . . a user interface 118n), a singular user interface 120, and a housing 122.

The charging base 102 can be configured to secure and provide power to one or more of the storage and charging containers 110. The charging base 102 can vary in size based on the size of the modular storage and charging system 100. For example, the charging base 102 can be configured to hold two, four, six, eight, ten, twelve, twenty, or more of the storage and charging containers 110 in varying arrangements. For example, the modular storage and charging system 100, as shown in FIG. 1, can be configured to receive one or more of the storage and charging containers 110 along plane 104 and can be configured to receive one or more storage and charging containers (e.g., the storage and charging container 110) along a plane into (and out of) the page.

In examples, the charging base 102 can include a wheel assembly 106. The wheel assembly 106 can be configured to make the modular storage and charging system 100 portable, such that the wheel assembly 106 can be moved around the room after the modular storage and charging system 100 is assembled. This permits the assembly of the modular storage and charging system 100 to occur in one location and the use (e.g., the storage and charging of mobile electronic devices) to occur in a second location. As discussed herein, the wheel assembly 106 can include one or more locks to prevent unintended movement of the modular storage and charging system 100.

In examples, the charging base 102 can include the power adapter 108. The power adapter 108 can be configured to be plugged into one or more standard outlets (e.g., 120 volts or 220 volts) to provide power to the modular storage and charging system 100. For example, when more storage and charging containers are used on the modular storage and charging system 200, the power adapter 108 can be connected to more outlets to provide more available power to the modular storage and charging system 200. The power adapter 108 can be configured to distribute the power to the various mobile electronic devices attached to the power adapter 108 via the charging base 102.

As shown in FIG. 1, the power adapter 108 can be connected to, or integral to, the charging base 102. In other examples, the power adapter 108 can be a separate unit that attaches to the charging base 102 and can be moved separately from the charging base 102. Such a system (where the power adapter 108 is not directly connected (or integral) to the charging base 102) can permit the power adapter 108 and not the rest of the modular storage and charging system 100 (e.g., the charging base 102), be near a power outlet to permit greater flexibility in the placement of the modular storage and charging system 100.

Each storage and charging container of the storage and charging containers 110 can be configured to receive and store one or more mobile electronic devices 114. The storage and charging containers can be attached and electronically connected to the modular storage and charging system 100 via the charging base 102 or via another storage and charging container 110 (e.g., in a plane perpendicular or substantially perpendicular to the plane 104). Each storage and charging container 110 can be separately securable such that only the owner of the mobile electronic device stored within the storage and charging container 110 can access a respective storage and charging container 110. Each storage and charging container 110 can include a charging interface 112.

The charging interface 112 can be disposed within each of the storage and charging containers 110 (e.g., the storage and charging container 110a, the container 110b, the storage and charging container 110c, the storage and charging container 110d, or the storage and charging container 110n . . . ) and connected to the power adapter 108 via another storage container (e.g., the container 110b can be connected to the power adapter 108 via the storage and charging container 110a, and the storage and charging container 110c and be connected to the power adapter 108 via the container 110b and the storage and charging container 110c). In some examples, the storage and charging containers can have side-to-side connections, such that the storage and charging container 110d can be connected to the power adapter 108 via storage and charging container 110c, the storage and charging container 110b, and storage and charging container 110a.

The charging interface 112 can be configured to convey a charge to one or more of the mobile electronic devices 114 stored within the storage and charging container 110. The charging interface 112 can convey a charge to the mobile electronic device 114 through a wired or wireless connection with the mobile electronic device 114. The charging interface 112 can include one or more of various wired attachments for common mobile electronic devices (e.g., USB Type-A, Micro-USB, USB Type-C, Lightning, Thunderbolt, magnetic or other power connectors, various proprietary mobile electronic device chargers, multiport adapters, or the like). Thus, for the charging interface 112 to convey a charge to the mobile electronic device 114, one or more mobile electronic devices can be wirelessly connected to the charging interface 112 while one or more other mobile electronic devices are connected via a wired attachment, all of the mobile electronic devices can be connected via a wired attachment, or all of the mobile electronic devices can be wirelessly connected.

The mobile electronic device 114 can be a user's mobile electronic device. The mobile electronic device 114 can be any of, for example, a personal computer (PC), a tablet, a personal digital assistant (PDA), a mobile telephone (e.g., a smartphone), a smartwatch or other wearable device, a mobile gaming device, a battery pack, or the like. A user can engage with the modular storage and charging system 100 to store and charge the mobile electronic device 114 within any of the storage and charging containers 110 that are unlocked.

Each of the storage and charging containers 110 can include a locking mechanism 116. The locking mechanism 116 can be configured to lock the storage and charging container 110 once the user's mobile electronic device 114 is within the storage and charging container 110 and connected to the charging interface 112. The locking mechanism 116 can be configured to remain locked until the owner of the mobile electronic device 114 returns to retrieve their mobile electronic device 114. The locking mechanism 116 can include a mechanical locking device (e.g., deadbolt lock, cam lock, or the like), an electromagnetic lock, a cylinder lock, or the like). The locking mechanism 116 can be controlled via a pin-pad, a digital code, a user interface, via a proximity-based communication protocol (e.g., Near Field Communication NFC)), a scanner (e.g., to scan a barcode, a QR code, etc.), a biometric reader (e.g., a fingerprint scanner, a camera, etc.), or the like.

As shown in FIG. 1, each storage and charging container 110 can include a unique user interface (e.g., the user interface 118a, the user interface 118b, . . . user interface 118n), which can be integral, or attached to, each the storage and charging container 110. In examples, the modular storage and charging system 100 can have a single user interface 120, that can be in communication with each of the storage and charging container and the power adapter 108 to control the charge and storage of the mobile electronic devices 114. In examples, the single user interface 120, which can control and communicate with all the storage and charging containers 110 connected to the modular storage and charging system 100 can be integral to the charging base 102, the housing 122, or a standalone device, such as a display, monitor, or other computing device, that is in communication with one or more components of the modular storage and charging system 100.

For example, the user interface 118 can interact with the locking mechanism 116 to lock or unlock the locking mechanism 116 via a command, combination, or other indicator provided by the owner of the mobile electronic devices 114 stored within the storage and charging container 110.

The housing 122 can be configured to hold each of the storage and charging containers 110 installed onto the charging base 102 together during the use of the modular storage and charging system 100. The housing 122 can prevent the storage and charging containers (e.g., the storage and charging container 110a, the container 110b, the storage and charging container 110c, the storage and charging container 110d, or the storage and charging container 110n . . . ) from being removed from the modular storage and charging system 100 and can help maintain the security of the mobile electronic devices 114 during storage and charging in their respective storage and charging container 110.

As shown in FIG. 1, the housing 122 can be a bar, tubing, or the like, that surrounds each of the storage and charging containers 110 connected to the modular storage and charging system 100, and can attach to the charging base 102 to hold the charging base 102 and the storage and charging containers 110 together. The housing 122 can include a plate that extends an entire width (into or out of the page) of the charging base 102 or can be tubes that span the width of the charging base 102. In examples, the housing 122 can be configured to overlap the storage and charging container 110 at least partially to help secure them within the modular storage and charging system 100. The housing 122 can be locked to the charging base 102 or can physically prevent the removal of the storage and charging containers.

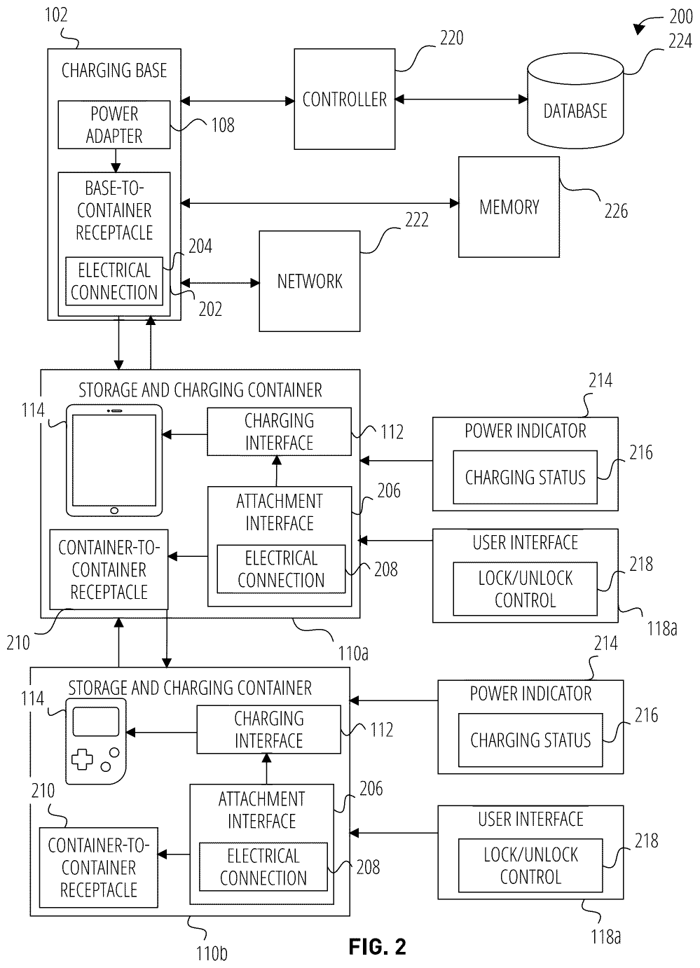

The charging base 102 can also include a sensor 124. The sensor 124 can be configured to detect various states of the modular storage and charging system 100. For example, the sensor 124 can include a proximity sensor to determine that the housing 122 is completely installed within the charging base 102. Thus, the sensor 124 can detect when the housing 122 is removed from the charging base 102 during the operation of the modular storage and charging system 100 and generate an alert. The alert can be an audible alert at the modular storage and charging system 100 or a silent alert sent via the internet (e.g., the network 224 (FIG. 2)) to the administrator of the modular storage and charging system 100. The sensor 124 can also include an accelerometer to detect quick movements of the modular storage and charging system 100, which could be indicative of an attempted theft of one or more of the storage and charging containers or the mobile electronic devices stored therein.

FIG. 2 illustrates a block diagram of an example modular storage and charging system 200 for modular storage and charging of mobile electronic devices mobile electronic device 114. The modular storage and charging system 200 (e.g., the modular storage and charging system 100) can be configured to store, secure, and charge one or more mobile electronic devices 114 within the storage and charging containers 110 attached to the modular storage and charging system 200.

As shown in FIG. 2, the charging base 102 can include a base-to-container receptacle 202 having an electrical connection 204. The base-to-container receptacle 202 can be configured to removably couple any of the storage and charging container 110 to the charging base 102. The electrical connection 204 can electronically connect each of the storage and charging containers 110 connected to the charging base 102 to the power adapter 108 to provide power to each power adapter 108 of the storage and charging containers 110 connected to the charging base 102.

Each storage and charging container of the storage and charging containers 110 can include an attachment interface 206 having an electrical connection 208, and a container-to-container receptacle 210. The attachment interface 206 is configured to be coupled to the base-to-container receptacle 202 to removably couple their respective storage and charging container 110 to the charging base 102. The attachment interface 206 is configured to electrically connect to the electrical connection 204 as the attachment interface 206 is coupled to the base-to-container receptacle 202. The electrical connection 208 is also electrically connected to the charging interface 112 such that the charging interface 112 is connected to the power adapter 108 via the electrical connection 204 and the electrical connection 208. As such, the charging interface 112 can convey a charge to the mobile electronic device 114 within the storage and charging container 110 from the charging interface 112 via the connection between the electrical connection 208 of the attachment interface 206 and the base-to-container receptacle 202 of the electrical connection 204, which is electrically connected, directly or indirectly, to the power adapter 108.

Each of the storage and charging containers 110 can include a container-to-container receptacle 210. The container-to-container receptacle 210 of a first container (e.g., storage and charging container 110a) can be configured to attach to the attachment interface 206 of a second container (e.g., the storage and charging container 110b) to connect the electrical connection 208 to the electrical connection 204. The stacking of the modular storage and charging system 100 will be discussed in more detail herein.

The modular storage and charging system 200 (e.g., the modular storage and charging system 100), or any one or more of the charging base 102, the storage and charging containers 110, the housing 122, or the user interface 118 can include a power indicator 216 having a charging status 218 of each mobile electronic device 114 stored within the storage and charging containers 110. The power indicator 216 can be a display, or other visual indicator, which can communicate the charging status 218 of the mobile electronic devices 114 within each of the storage and charging containers 110 to the owner of the mobile electronic device 114 within their respective storage and charging container 110. In examples, the power indicator 216 can be connected to a network 224 (e.g., the internet) via the charging base 102 to communicate the charging status 218 to the owner of the mobile electronic device 114 via the network 224. As such, the power indicator 216 can provide a live update on the charging status 218 of the user's mobile electronic device 114 within the storage and charging container 110.

As discussed above with reference to FIG. 1, the modular storage and charging system 200 (e.g., the modular storage and charging system 100) or each of the storage and charging containers 110 can also include the user interface 118. The user interface 118 can include a lock/unlock control 220. The lock/unlock control 220 can lock or unlock the locking mechanism 116 (FIG. 1) based on inputs from the owner of the mobile electronic device 114 on the user interface 118. In examples, the user can enter a combination, code, biometric print (e.g., thumbprint or eye scan), swipe password, any combination thereof, or the like, to lock the locking mechanism 116, and can use the same combination, code, biometric print, swipe password to unlock the storage and charging container 110 to remove the mobile electronic device 114.

The modular storage and charging system 200 can also include a controller 222, a network 224, a database 226, or a memory 228. As discussed herein, the network 224 can be a remote network to permit the modular storage and charging system 200 (e.g., the modular storage and charging system 100) to communicate with the owner of the mobile electronic device 114 stored within the storage and charging system, or with another system that monitors the use or power loading of the storage and charging system. The network 224 can also enable the modular storage and charging system 200 to communicate with an administrator of the modular storage and charging system 200. Such communications with the administrator can include charging status, usage statistics, power statistics, alerts or alarms, or the like.

The database 226 or the memory 228 can be configured to store the user codes, passwords, or the like, which can be recalled later to verify the correct password is entered before unlocking the storage and charging container 110. In other examples, the codes, passwords, or the like can be stored at the storage and charging container.

Memory 228 can include instructions that can configure the controller 222 to control the power loading of the modular storage and charging system 200. For example, the instructions can configure the controller 222 to disconnect power to the charging interface 112 of storage and charging containers 110 that are not actively storing or charging a mobile electronic device 114. The instructions can configure the controller 222 to alter the power supplied to the mobile electronic device 114 as the charging status 218 of the mobile electronic device 114 within the storage and charging container 110 changes. The instructions stored on memory 228 can also configure controller 222 to transmit the charging status 218 to the owner of the mobile electronic devices.

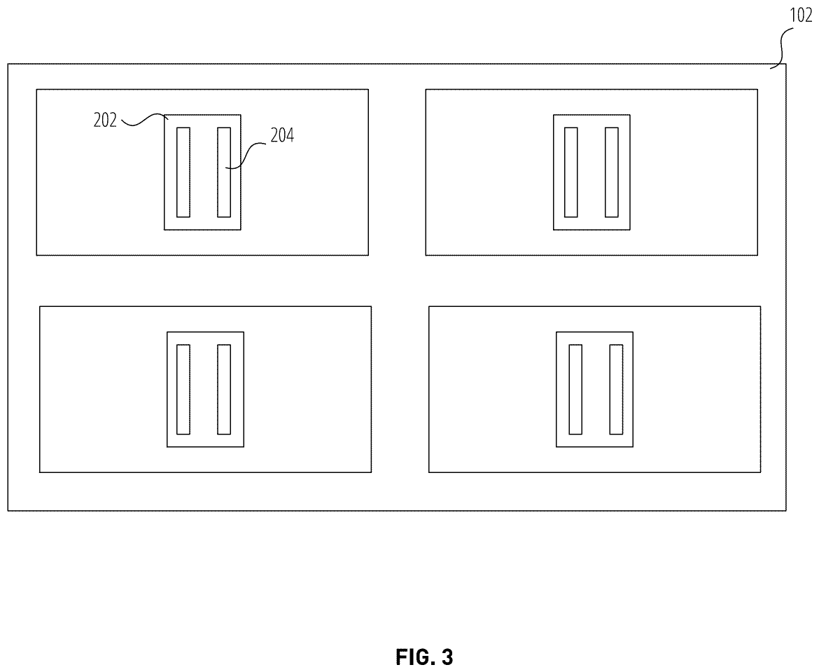

FIG. 3 illustrates a schematic diagram of an example of a charging base 102. As discussed herein, and shown in FIG. 3, the charging base 102 can include one or more base-to-container receptacles 202. Each base-to-container receptacle 202 can include an electrical connection 204. Each base-to-container receptacle 202 can be configured to receive a storage and charging container 110 (FIG. 1) to couple the storage and charging container 110 to the charging base 102 and provide power to the storage and charging container 110 via the electrical connection 204. The charging base 102 can have any number of base-to-container receptacles 202. For example, as shown in FIG. 3, the charging base 102 can include a two-by-two grid of base-to-container receptacles 202. In other examples, the charging base 102 can include any grid that fits within a ten-by-ten grid, such as a three-by-one, three by two, four-by-four, eight by two, or the like. In some examples, the footprint of the charging base 102 can be increased even more to include larger capacities.

The electrical connection 204 can be connected to the power adapter 108 (FIG. 1) to electrically connect the storage and charging container 110 to the power adapter 108. In examples, the electrical connection 204 can include magnetic materials to help secure the storage and charging container 110 to the base-to-container receptacle 202 and to ensure a connection between the electrical connection 204 and the electrical connection 208 (FIG. 2) of the attachment interface 206 (FIG. 2).

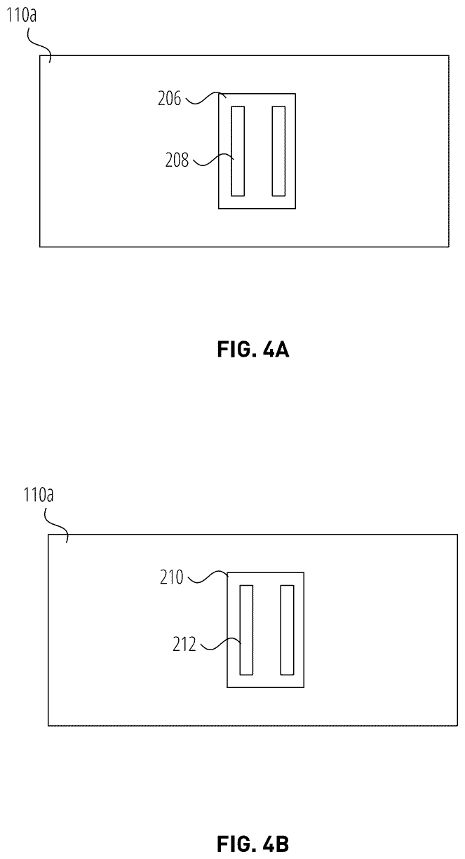

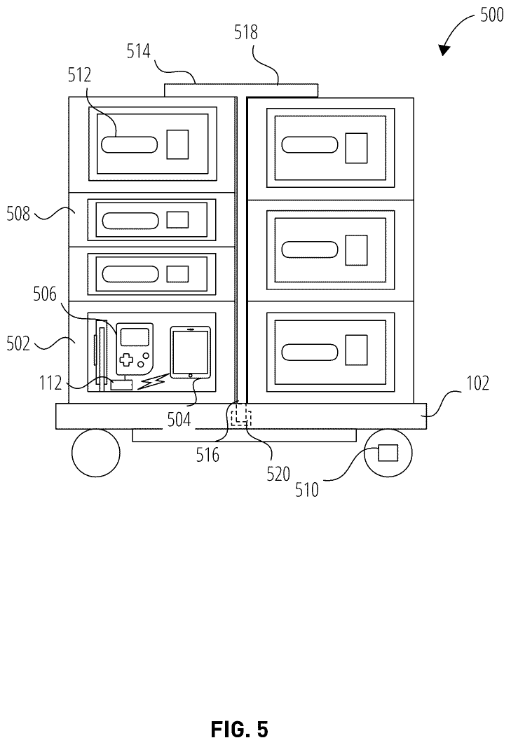

FIG. 4A and FIG. 4B will be discussed together. FIG. 4A illustrates a schematic diagram of a bottom view of the storage and charging container 110. FIG. 4B illustrates a schematic diagram of a top view of the storage and charging container 110. As shown in FIG. 4A, the storage and charging container 110 can include an attachment interface 206, which can include an electrical connection 208.

The attachment interface 206 can be configured to removably couple the storage and charging container 110 to the charging base 102 via connection with the base-to-container receptacle 202. The attachment interface 206 can also be configured to align the electrical connection 208 with the electrical connection 204 of the base-to-container receptacle 202 to ensure that the electrical connection 208 is electrically coupled to the electrical connection 204. The electrical connection 208 can be configured to electrically couple to the electrical connection 204 such that the electrical connection 204 electrically connects the electrical connection 208 to the power adapter 108. The electrical connection 208 can include magnetic material to help facilitate the connection between the electrical connection 208 and the electrical connection 204.

As shown in FIG. 4B, the storage and charging container 110 can include a container-to-container receptacle 210, which can include a second electrical connection 212. The container-to-container receptacle 210 can be configured to removably couple a first storage and charging container 110 to a second storage and charging container 110. The container-to-container receptacle 210 can also be configured to electrically connect the second electrical connection 212 to the electrical connection 208 to provide power to the second of the storage and charging container 110 connected to the first storage and charging container 110. The connection between the electrical connection 208 and the second electrical connection 212 can electrically connect the second electrical connection 212 to the power adapter 108 via the connection between the electrical connection 208 of the attachment interface 206 of the first storage and charging container 110 and the electrical connection 204 for the respective base-to-container receptacle 202 of the charging base 102.

As shown in FIG. 4A and FIG. 4B, the container-to-container receptacle 210 can be located opposite the attachment interface 206 for each storage and charging container 110. The combination of each storage and charging container 110, including the attachment interface 206 and the container-to-container receptacle 210, can permit the storage and charging containers 110 to be daisy-chained together, which can permit electrical charge to be conveyed therethrough via the electrical connection 208 and the second electrical connection 212, respectively.

In examples, the base-to-container receptacle 202 and the container-to-container receptacle 210 can be female adapters configured to receive the attachment interface 206, which can be a male adapter. In other examples, the base-to-container receptacle 202 and the container-to-container receptacle 210 can be male adapters configured to be inserted into the attachment interface 206, which can be a female adapter.

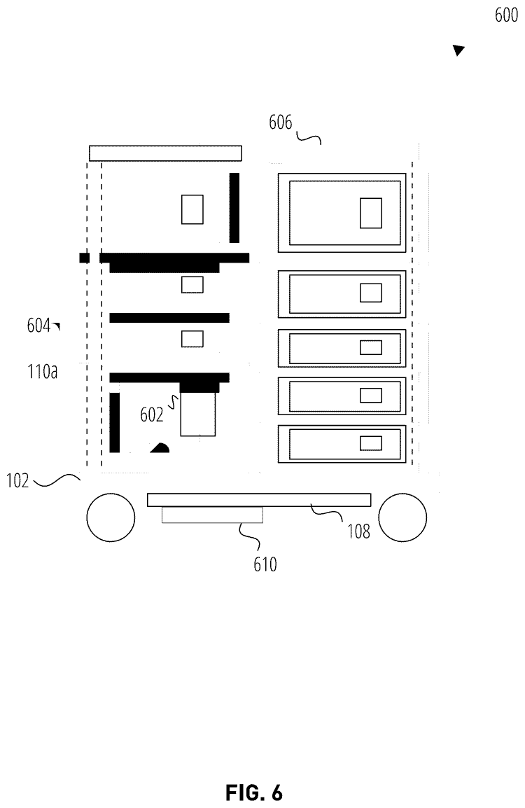

FIG. 5 illustrates a schematic diagram of an example of a module modular storage and charging system 500. The modular storage and charging system 500 can include different sizes or types of storage and charging devices (e.g., a first storage and charging container 502 and a second storage and charging container 508), which can be similar to the storage and charging containers 110 (e.g., storage and charging container 110a, . . . storage and charging container 110n from FIG. 1).

The different sizes of the storage and charging container (e.g., the size difference between the first storage and charging container 502 and the second storage and charging container 508) can help the storage and charging containers accommodate mobile electronic devices 114 (FIG. 1) of different sizes. For example, the first storage and charging container 502 can receive larger, or more, mobile electronic devices than the second storage and charging container 508 because the first storage and charging container 502 is larger than the second storage and charging container 508. In contrast, because of the reduced size of the second storage and charging container 508, the modular storage and charging system 500 can hold more second storage charging containers 508 than first storage and charging containers 502 within the same envelope, which can provide access to the modular storage and charging system 500 to more users.

In other words, the different sizes of the storage and charging containers can help the modular storage and charging system 500 be more modular or customizable for the required use of the system. For example, if the modular storage and charging system 500 needs to maximize the number of unique users that can store devices within the modular storage and charging system 500 the second storage and charging container 508 can be used. In another example, such as a work conference, if the modular storage and charging system 500 needs to be able to accommodate business professionals with many mobile electronic devices, the first storage and charging container 502 can be used.

The modular storage and charging system 500 (e.g., the modular storage and charging system 100 or the modular storage and charging system 200) can include another example of a housing 514. The housing 514 can be configured to secure the storage and charging containers (e.g., the first mobile electronic device 504 and the power indicator 512, any of the storage and charging containers 110, or the like) to the charging base 102 to prevent unintentional removal of the storage and charging containers from the charging base 102. In examples, the housing 514 can have an overhang that covers at least a portion of the storage and charging container to help secure the storage and charging containers on the charging base 102.

The housing 514 can extend between a first section 516 and a second section 518. The first section 516 can be configured to be inserted into a locking channel 520 of the charging base 102 to secure the housing 514 to the charging base 102. The housing 514 can extend from the charging base 102, between the storage and charging container 110 toward the second section 518. The second section 518 can extend laterally across the top of the top row of the storage and charging containers 110. In examples, the first section 516 can be adjustable such that a length of the first section 516 can be adjusted to accommodate different heights of the storage and charging containers 110 attached to the charging base 102.

The locking channel 520 of the charging base 102 can configured to receive the housing 514 and to lock the housing 514 in place during the use of the modular storage and charging system 500. The locking channel 520 can be controlled via a controller (e.g., controller 222 (FIG. 2), a remote command, or with a mechanical lock and key. The locking channel 520 can include a sensor that can detect the presence of the housing 514 such that the locking channel 520 automatically operates to hold the housing 514 upon the housing 514 being inserted within the locking channel 520.

As shown in FIG. 5, each storage and charging container 110 can include a power indicator 512 (e.g., the power indicator 216 (FIG. 2)), which can be configured to show a battery status for each device stored and charging within each of the storage and charging containers. In examples, as discussed in FIG. 2, the power indicator 512 can also be a separate unit, which can display the charging status of each of the mobile electronic devices being stored and charged within the modular storage and charging system 500. The power indicator 512 can be in communication with the network 224 to communicate with an administrator of the modular storage and charging system 500 or an owner of the mobile electronic devices within the modular storage and charging system 500. For example, the power indicator 512 can transmit a signal via the network 224 to the administrator to indicate that one or more devices are done charging. The administrator can initiate idle time penalties for the overuse of the storage and charging container by the user of the respective charged mobile electronic devices. The power indicator 512 can communicate via the network 224 with the owner of the mobile electronic device within the storage and charging container to alert them that their device is almost done charging, done charging, to provide a current battery level, or send an error message when the charging of their device has been interrupted.

As also shown in FIG. 5, the storage and charging containers can be configured to store more than one type of mobile electronic device (e.g., mobile electronic device 114 (FIG. 1). For example, the storage and charging containers can store and charge a first mobile electronic device 504 and a second mobile electronic device 506. The first mobile electronic device 504 and the second mobile electronic device 506 can also be connected to the charging interface 112 via a wired or wireless connection.

The wheel assembly 510 (e.g., the wheel assembly 106 (FIG. 1)) can be attached to the charging base 102 opposite the base-to-container receptacle 202 (FIG. 2). The wheel assembly 510 can be operable between a locked configuration and an unlocked configuration. In the locked configuration, the wheel assembly 510 can prevent the modular storage and charging system 500 from being moved around the environment of use. In the unlocked configuration, the wheel assembly 510 can permit the movement of the modular storage and charging system 500 around the environment of use. In examples, the wheel assembly 510 can be operated with a controller (e.g., the controller 222 (FIG. 2)), as indicated by the user interface or a network connection with the owner of the modular storage and charging system 500. Such connections can prevent unintended movement of the modular storage and charging system 500 without permission from the administrator of the modular storage and charging system 500.

FIG. 6 illustrates a schematic diagram of an example of a module modular storage and charging system 600 (e.g., the modular storage and charging system 100, the modular storage and charging system 200, the modular storage and charging system 500, or the like). The mobile electronic device 602 (e.g., the mobile electronic device 114 (FIG. 1), the first mobile electronic device 504 (FIG. 5), or the second mobile electronic device 506 (FIG. 5)) can be a tablet device as shown in FIG. 6.

Each storage and charging container 110 can include locking slots 604. The locking slots 604 can be configured to receive the housing 606 to secure the storage and charging containers 110 to the charging base 102. As shown in FIG. 6, the storage and charging containers 110 can be installed on the charging base 102 such that the locking slots 604 are aligned and the housing 606 can be installed therein and attached to the charging base 102. The housing 606 can extend beyond the storage and charging container 110 farthest from the charging base 102 to help secure all of the storage and charging containers 110 attached to the charging base 102. FIG. 6 also shows another example of the modularity of the modular storage and charging system 600, which can use multiple of the storage and charging containers 110 of different sizes, which can tailor the modular storage and charging system 600 to the required use of the modular storage and charging system 600.

The charging system 600 can also include a battery 610. As shown in FIG. 6, the battery 610 can be attached to the power adapter 108. The battery 610 can also be integral to the charging base 102 or removably attached to the charging base 102 or the housing 606. In examples, the battery 610 can function as a battery backup to reduce surges as power is lost in the building. The battery 610 can also be an overload backup, which can help the power adapter 108 provide power to all of the mobile electronic devices stored within the charging system 600 during peak power requirement times of the charging system 600. In examples, the power adapter 108 can charge the battery 610 during times of excess power (e.g., low utilization of the charging system 600), and can draw from the battery 610 during times of power demands above the capabilities of the power adapter 108. The charging system 600 can also utilize solar panels to charge the battery 610 or to charge mobile electronic devices via the power adapter 108.

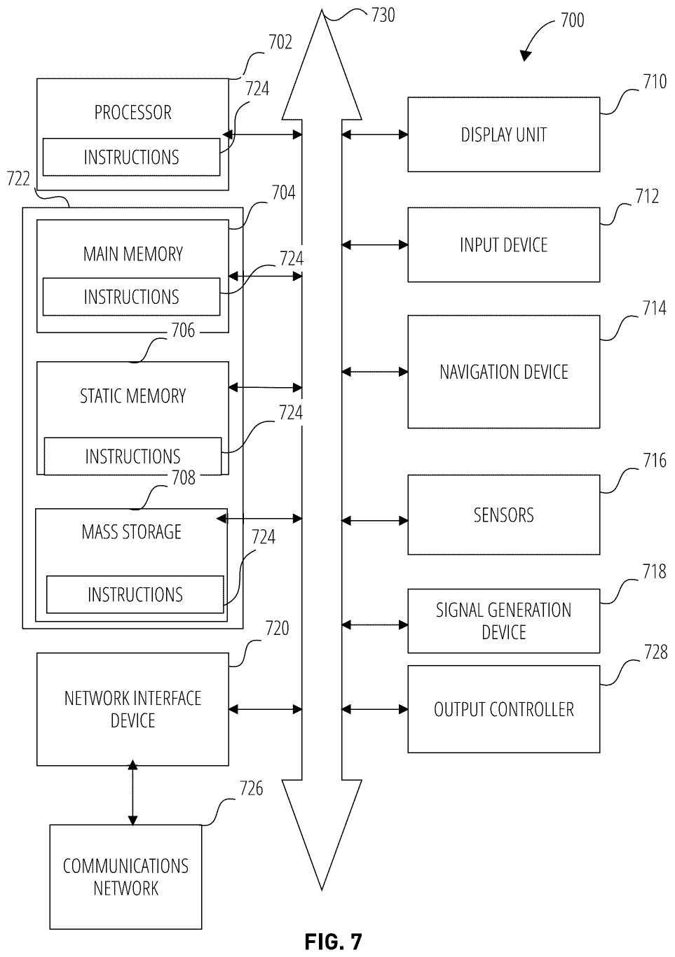

FIG. 7 illustrates a block diagram of an example machine 700 upon which any one or more of the techniques (e.g., methodologies) discussed herein may perform. Examples, as described herein, may include, or may operate by, logic or a number of components, or mechanisms in the machine 700. Circuitry (e.g., processing circuitry) is a collection of circuits implemented in tangible entities of the machine 700 that include hardware (e.g., simple circuits, gates, logic, etc.). Circuitry membership may be flexible over time. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a machine readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine readable medium elements are part of the circuitry or are communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time. Additional examples of these components with respect to the machine 700 follow.

In alternative examples, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine 700 may include a hardware processor 702 (e.g., a central processing unit (CPU), a graphics processing unit (GPU), a hardware processor core, or any combination thereof), a main memory 704, a static memory (e.g., memory or storage for firmware, microcode, a basic-input-output (BIOS), and mass storage 708 (e.g., hard drives, tape drives, flash storage, or other block devices) some or all of which may communicate with each other via an interlink 730 (e.g., bus). The machine 700 may further include a display unit 710, an alphanumeric input device 712 (e.g., a keyboard), and a user interface (UI) navigation device 714 (e.g., a mouse). In an example, the display unit 710, input device 712 and UI navigation device 714 may be a touch screen display. The machine 700 may additionally include a signal generation device 718 (e.g., a speaker), a network interface device 720, and one or more sensors 716, such as a global positioning system (GPS) sensor, compass, accelerometer, or other sensor. The machine 700 may include an output controller 728, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the processor 702, the main memory 704, the static memory 706, or the mass storage 708 may be, or include, a machine readable medium 722 on which is stored one or more sets of data structures or instructions 724 (e.g., software) embodying or utilized by any one or more of the techniques or functions described herein. The instructions 724 may also reside, completely or at least partially, within any of registers of the processor 702, the main memory 704, the static memory 706, or the mass storage 708 during execution thereof by the machine 700. In an example, one or any combination of the hardware processor 702, the main memory 704, the static memory 706, or the mass storage 708 may constitute the machine readable media 722. While the machine readable medium 722 is illustrated as a single medium, the term “machine readable medium” may include a single medium or multiple media (e.g., a centralized or distributed database, and/or associated caches and servers) configured to store the one or more instructions 724.

The term “machine-readable medium” may include any medium that is capable of storing, encoding, or carrying instructions for execution by the machine 700 and that cause the machine 700 to perform any one or more of the techniques of the present disclosure, or that is capable of storing, encoding or carrying data structures used by or associated with such instructions. Non-limiting machine-readable medium examples may include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine-readable media that do not include transitory propagating signals. Specific examples of non-transitory machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

In an example, information stored or otherwise provided on the machine readable medium 722 may be representative of the instructions 724, such as instructions 724 themselves or a format from which the instructions 724 may be derived. This format from which the instructions 724 may be derived may include source code, encoded instructions (e.g., in compressed or encrypted form), packaged instructions (e.g., split into multiple packages), or the like. The information representative of the instructions 724 in the machine readable medium 722 may be processed by processing circuitry into the instructions to implement any of the operations discussed herein. For example, deriving the instructions 724 from the information (e.g., processing by the processing circuitry) may include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 724.

In an example, the derivation of the instructions 724 may include assembly, compilation, or interpretation of the information (e.g., by the processing circuitry) to create the instructions 724 from some intermediate or preprocessed format provided by the machine readable medium 722. The information, when provided in multiple parts, may be combined, unpacked, and modified to create the instructions 724. For example, the information may be in multiple compressed source code packages (or object code, or binary executable code, etc.) on one or several remote servers. The source code packages may be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 724 may be further transmitted or received over a communications network 726 using a transmission medium via the network interface device 720 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), LoRa/LoRaWAN, or satellite communication networks, mobile telephone networks (e.g., cellular networks such as those complying with 3G, 4G LTE/LTE-A, or 5G standards), Plain Old Telephone (POTS) networks, and wireless data networks (e.g., Institute of Electrical and Electronics Engineers (IEEE) 702.11 family of standards known as Wi-Fi®, IEEE 702.15.4 family of standards, peer-to-peer (P2P) networks, among others. In an example, the network interface device 720 may include one or more physical jacks (e.g., Ethernet, coaxial, or phone jacks) or one or more antennas to connect to the communications network 726. In an example, the network interface device 720 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 700, and includes digital or analog communications signals or other intangible medium to facilitate communication of such software. A transmission medium is a machine-readable medium.

The following, non-limiting examples, detail certain aspects of the present subject matter to solve the challenges and provide the benefits discussed herein, among others.

Example 1 is a modular system for storing and charging mobile electronic devices, the modular system comprising: a charging base including: a power adapter to provide power to the modular system; and a first base-to-container receptacle including: a first electrical connection connected to the power adapter; a first storage and charging container configured to be removably coupled to the first base-to-container receptacle, the first storage and charging container including: a first charging interface disposed within the first storage and charging container, the first charging interface connected to the power adapter via the first electrical connection, the first charging interface configured to convey a first charge from the power adapter to a first mobile electronic device; and a first container-to-container receptacle including: a second electrical connection connected to either the first electrical connection or the power adapter; and a second storage and charging container configured to be removably coupled to the first container-to-container receptacle, the second storage and charging container including: a second charging interface disposed within the second storage and charging container, the second charging interface connected to the power adapter via the second electrical connection, the second charging interface configured to convey a second charge from the power adapter to a second mobile electronic device.

In Example 2, the subject matter of Example 1 optionally includes wherein the first storage and charging container comprises: a first locking mechanism configured to lock the first storage and charging container to secure the first mobile electronic device within the first storage and charging container.

In Example 3, the subject matter of Example 2 optionally includes wherein the second storage and charging container comprises: a second locking mechanism configured to lock the second storage and charging container to secure the second mobile electronic device stored within the second storage and charging container.

In Example 4, the subject matter of any one or more of Examples 1-3 optionally include wherein the charging base comprises: a second base-to-container receptacle located adjacent to the first base-to-container receptacle, the second base-to-container receptacle including: a third electrical connection connected to the power adapter.

In Example 5, the subject matter of Example 4 optionally includes a third storage and charging container configured to be removably coupled to the second base-to-container receptacle, the third storage and charging container including: a third locking mechanism configured to lock the first storage and charging container to secure the first mobile electronic device within the first storage and charging container; and a third charging interface disposed within the third storage and charging container, the third charging interface connected to the power adapter via the third electrical connection, the third charging interface configured to convey a third charge from the power adapter to a third mobile electronic device.

In Example 6, the subject matter of Example 5 optionally includes wherein each of the first storage and charging container, the second storage and charging container, and the third storage and charging container comprises: a power indicator configured to indicate a charging status of each respective mobile electronic device inside each respective storage and charging container.

In Example 7, the subject matter of any one or more of Examples 5-6 optionally include wherein at least one of the first charging interface, the second charging interface, or the third charging interface are configured to provide charge wirelessly to the first mobile electronic device, the second mobile electronic device, and the third mobile electronic device, respectively.

In Example 8, the subject matter of any one or more of Examples 5-7 optionally include wherein at least one of the first charging interface, the second charging interface, or the third charging interface are configured to charge more than one mobile electronic device simultaneously.

In Example 9, the subject matter of any one or more of Examples 5-8 optionally include wherein the first mobile electronic device is a laptop.

In Example 10, the subject matter of any one or more of Examples 5-9 optionally include wherein the first mobile electronic device is a cell phone.

In Example 11, the subject matter of any one or more of Examples 5-10 optionally include wherein the first mobile electronic device is a cellphone, and wherein the second mobile electronic device is a laptop.

In Example 12, the subject matter of any one or more of Examples 1-11 optionally include a housing attachable to the charging base and configured to secure the first storage and charging container and the second storage and charging container to the charging base.

Example 13 is a modular charging system comprising: a charging base including: a power adapter to provide power to the modular charging system; and a plurality of base-to-container receptacles, each base-to-container receptacles including: a first electrical connection connected to the power adapter; and a plurality of storage and charging containers, each storage and charging container including: a charging interface disposed within each storage and charging container, the charging interface connected to the power adapter and configured to convey a charge from the power adapter to a mobile electronic device stored within each storage and charging container; and a container-to-container receptacle including: a second electrical connection connected to either the first electrical connection or the power adapter; wherein each storage and charging container configured to be removably coupled to the charging base via any one of the plurality of base-to-container receptacles, and configured to be removably coupled to another storage and charging container via the container-to-container receptacle.

In Example 14, the subject matter of Example 13 optionally includes a locking member configured to secure each storage and container of the plurality of storage and charging containers secured to the modular charging system to the charging base.

In Example 15, the subject matter of any one or more of Examples 13-14 optionally include wherein each of the plurality of storage and charging containers comprises a locking mechanism configured to individually lock each storage and charging container of the plurality of storage and charging containers.

In Example 16, the subject matter of any one or more of Examples 13-15 optionally include wherein the charging base comprises: a wheel assembly attached to the charging base opposite the plurality of base-to-container receptacles, the wheel assembly operable between a locked configuration and an unlocked configuration.

In Example 17, the subject matter of Example 16 optionally includes wherein in the locked configuration, the wheel assembly prevents movement around a room of the modular charging system, and wherein in the unlocked configuration, the wheel assembly permits movement around a room of the modular charging system.

In Example 18, the subject matter of any one or more of Examples 13-17 optionally include wherein each storage and charging container is configured to hold at least a first mobile electronic device and a second mobile electronic device.

In Example 19, the subject matter of Example 18 optionally includes wherein the first mobile electronic device is a cell phone, and wherein the second mobile electronic device is a laptop.

In Example 20, the subject matter of Example 19 optionally includes wherein each storage and charging container of the plurality of storage and charging containers comprises: a power indicator configured to indicate a charging status of each of the first mobile electronic device and the second mobile electronic device stored within each storage and charging container.

Example 21 includes a system, apparatus, or a method including any element of any of Examples 1-20.

The above-detailed description includes references to the accompanying drawings, which form a part of the detailed description. The drawings show, by way of illustration, specific examples that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5). Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

The above description is intended to be illustrative, and not restrictive. For example, the above-described examples (or one or more aspects thereof) may be used in combination with each other. Other examples may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the examples should be determined with reference to the appended claims, along with the full scope of equivalents to which such claims are entitled.

What is claimed is:

1. A modular system for storing and charging mobile electronic devices, the modular system comprising:
a charging base including:
a power adapter to provide power to the modular system; and
a first base-to-container receptacle including a first electrical connection connected to the power adapter;
a first storage and charging container configured to be removably coupled to the first base-to-container receptacle, the first storage and charging container including:
a first charging interface disposed within the first storage and charging container, the first charging interface connected to the power adapter via the first electrical connection, the first charging interface configured to convey a first charge from the power adapter to a first mobile electronic device; and
a first container-to-container receptacle including:
a second electrical connection connected to the first electrical connection; and
a second storage and charging container configured to be removably coupled to the first container-to-container receptacle, the second storage and charging container including:
a second charging interface disposed within the second storage and charging container, the second charging interface connected to the power adapter via the second electrical connection, the second charging interface configured to convey a second charge from the power adapter to a second mobile electronic device.

2. The modular system of claim 1, wherein the first storage and charging container comprises:
a first locking mechanism configured to lock the first storage and charging container to secure the first mobile electronic device within the first storage and charging container.

3. The modular system of claim 2, wherein the second storage and charging container comprises:
a second locking mechanism configured to lock the second storage and charging container to secure the second mobile electronic device stored within the second storage and charging container.

4. The modular system of claim 1, wherein the charging base comprises:
a second base-to-container receptacle located adjacent to the first base-to-container receptacle, the second base-to-container receptacle including:
a third electrical connection connected to the power adapter.

5. The modular system of claim 4, comprising:
a third storage and charging container configured to be removably coupled to the second base-to-container receptacle, the third storage and charging container including:
a third locking mechanism configured to lock the first storage and charging container to secure the first mobile electronic device within the first storage and charging container; and
a third charging interface disposed within the third storage and charging container, the third charging interface connected to the power adapter via the third electrical connection, the third charging interface configured to convey a third charge from the power adapter to a third mobile electronic device.

6. The modular system of claim 5, wherein each of the first storage and charging container, the second storage and charging container, and the third storage and charging container comprises:
a power indicator configured to indicate a charging status of each respective mobile electronic device inside each respective storage and charging container.

7. The modular system of claim 5, wherein at least one of the first charging interface, the second charging interface, or the third charging interface are configured to provide charge wirelessly to the first mobile electronic device, the second mobile electronic device, and the third mobile electronic device, respectively.

8. The modular system of claim 5, wherein at least one of the first charging interface, the second charging interface, or the third charging interface are configured to charge more than one mobile electronic device simultaneously.

9. The modular system of claim 5, wherein the first mobile electronic device is a laptop.

10. The modular system of claim 5, wherein the first mobile electronic device is a cell phone.

11. The modular system of claim 5, wherein the first mobile electronic device is a cellphone, and wherein the second mobile electronic device is a laptop.

12. The modular system of claim 1, comprising:
a housing attachable to the charging base and configured to secure the first storage and charging container and the second storage and charging container to the charging base.

13. A modular charging system comprising:
a charging base including:
a power adapter to provide power to the modular charging system; and
a plurality of base-to-container receptacles, each base-to-container receptacles including:
a first electrical connection connected to the power adapter; and
a plurality of storage and charging containers, each storage and charging container including:
a charging interface disposed within each storage and charging container, the charging interface connected to the power adapter and configured to convey a charge from the power adapter to a mobile electronic device stored within each storage and charging container; and
a container-to-container receptacle including:
a second electrical connection connected to either the first electrical connection or the power adapter;
wherein each storage and charging container configured to be removably coupled to the charging base via any one of the plurality of base-to-container receptacles, and configured to be removably coupled to another storage and charging container via the container-to-container receptacle.

14. The modular charging system of claim 13, comprising:
a locking member configured to secure each storage and container of the plurality of storage and charging containers secured to the modular charging system to the charging base.

15. The modular charging system of claim 13, wherein each of the plurality of storage and charging containers comprises a locking mechanism configured to individually lock each storage and charging container of the plurality of storage and charging containers.

16. The modular charging system of claim 13, wherein the charging base comprises:
a wheel assembly attached to the charging base opposite the plurality of base-to-container receptacles, the wheel assembly operable between a locked configuration and an unlocked configuration.

17. The modular charging system of claim 16, wherein in the locked configuration, the wheel assembly prevents movement around a room of the modular charging system, and wherein in the unlocked configuration, the wheel assembly permits movement around a room of the modular charging system.

18. The modular charging system of claim 13, wherein each storage and charging container is configured to hold at least a first mobile electronic device and a second mobile electronic device.

19. The modular charging system of claim 18, wherein the first mobile electronic device is a cell phone, and wherein the second mobile electronic device is a laptop.

20. The modular charging system of claim 19, wherein each storage and charging container of the plurality of storage and charging containers comprises:
a power indicator configured to indicate a charging status of each of the first mobile electronic device and the second mobile electronic device stored within each storage and charging container.
